(19) United States
(12) Patent Application Publication
(10) Pub. No.: US 2024/0119336 A1
(43) Pub. Date: Apr. 11, 2024

(54) METHODS AND SYSTEMS FOR ALLOCATING QUBITS ON A QUANTUM CHIP STRUCTURE REPRESENTED BY A GRAPH

(71) Applicant: 1QB Information Technologies Inc., Vancouver (CA)

(72) Inventors: Shengru REN, Seattle, WA (US); KaWai CHEN, Vancouver (CA); Navid GHADERMARZY, Burnaby (CA); Pooya RONAGH, Guelph (CA)

(21) Appl. No.: 18/489,733

(22) Filed: Oct. 18, 2023

Related U.S. Application Data
(63) Continuation of application No. PCT/IB2022/053658, filed on Apr. 19, 2022.
(60) Provisional application No. 63/176,650, filed on Apr. 19, 2021.

(51) Int. Cl. G06N 10/40; G06N 10/20; H03K 17/92

(52) U.S. Cl. CPC G06N 10/40; G06N 10/20; H03K 17/92

(57) ABSTRACT

The present disclosure may include methods, devices, and systems for constructing a routed circuit to allocate information qubits. The routed circuit may comprise at least one two-qubit gate and zero or more one-qubit gates on a quantum chip structure represented by a graph comprising vertices and edges.

### CROSS-REFERENCE

This application is a continuation of International Application No. PCT/IB2022/053658, filed Apr. 19, 2022, which claims the benefit of U.S. Provisional Application Ser. No. 63/176,650, filed Apr. 19, 2021, each of which is incorporated herein by reference in its entirety for all purposes.

### BACKGROUND

In classical computers, information may be stored as bits. Similarly, in quantum computers, information may be stored as “qubits” or “qudits.” There are various methods of realizing qubits and qudits using physical implementations. In at least some instances, a physical implementation may be limited by the number of neighboring qubits each qubit may interact with. In some cases, this is limited to nearest neighbors. However, interactions between qubits may be useful for implementing various quantum computing applications. For example, a quantum computer may exploit quantum entanglement and quantum superposition to perform calculations and/or to store information. Accordingly, when the qubits are not sufficiently near to interact with one another (or interact strongly enough), it may be advantageous to move the information stored in the qubits to qubits that are sufficiently near. The study of how to move the information around is sometimes referred to as the “qubit allocation problem,” also known as the “placement and routing problem.”

### SUMMARY

Disclosed herein is a middle-ground solution to the placement and routing problem that captures the efficiency of both heuristic and greedy approaches, and the effectiveness of dynamic programming in temporal decision-making problems.

The action of moving qubits to different locations may be achieved via inserting a SWAP gate into the quantum circuit that is to be executed on a quantum computer. However, since inserting extra gates into a circuit may increase the length of the circuit and consequently prolong the computation time, which may increase the likelihood of the accumulation of errors, it may be advantageous to devise a method which reduces the number of SWAP gates needed to be inserted in order to complete the computation of a circuit on a quantum computer. In at least some cases, a method which reduces the number of SWAP gates may be efficient, e.g., it takes less time, takes fewer gates, etc., than existing methods. In at least some cases, a method which reduces the number of SWAP gates may find fewer SWAP gates than existing methods or even find the minimum number of SWAP gates.

Recognized herein is the need for improved methods and systems that could overcome at least one of the identified drawbacks. The present disclosure provides methods and systems for constructing a routed circuit for allocating qubits on a quantum chip structure represented by a two-dimensional graph.

In an aspect, the present disclosure provides a method for constructing a circuit to allocate information qubits, said circuit comprising one or more quantum gates. The method may comprise: (a) obtaining a list of two-qubit quantum gates, wherein said list comprises at least one two-qubit quantum gate; (b) using a graph representative of a quantum chip structure to implement a placement procedure on said list of said two-qubit quantum gates to obtain an initial placement of said information qubits on said quantum chip structure; (c) implementing a routing procedure to construct a routed circuit for said information qubits comprising said list of two-qubit quantum gates using said initial placement, wherein said routing procedure comprises a scoring system comprising discounted and not discounted scores; and (d) providing an output representative of said routed circuit, wherein said output comprises an order of execution of said one or more quantum gates, and wherein said routed circuit is configured to allocate said information qubits on said quantum chip structure.

In some embodiments, the method further comprises constructing at least one member of the group consisting of: a list of layers of said two-qubit quantum gates, an ordered list of said two-qubit quantum gates, and a dependency graph. In some embodiments, said dependency graph comprises a directed acyclic graph (DAG). In some embodiments, constructing said DAG comprises, until an end of a list of not-yet-executed quantum gates from said list of two-qubit quantum gates, assigning each gate a level on said DAG.

In some embodiments, the method further comprises providing said output representative of said routed circuit to an intermediate communication interface comprising a quantum chip controller to instruct said quantum chip structure to execute in the order of said provided output file representative of said routed circuit. In some embodiments, said graph comprises vertices and edges, and wherein (b) comprises calculating a placement score based at least in part on distances between said vertices of said graph, wherein said vertices each corresponds to an information qubit of said information qubits. In some embodiments, said distances between said vertices are scaled by a constant factor exponentiated by a level in said DAG of a two-qubit quantum gate.

In some embodiments, the method further comprises: (a) computing a Hamiltonian path of said quantum chip structure, wherein said Hamiltonian path is a path traversing said graph passing through each vertex of said graph once; and (b) using said Hamiltonian path to place said two-qubit quantum gates to obtain said initial placement. In some embodiments, (b) comprises a randomized mixture of a greedy approach and a random approach. In some embodiments, (b) comprises implementing said placement procedure a number of times and using said placement score to select said initial placement.

In some embodiments, implementing said routing procedure comprises, until no executable gates remain unevaluated in a first level of said DAG: (a) identifying said executable gates in said first level of said DAG and registering them to said output representative of said routed circuit; (b) if one or more executable gates are identified in (a), then identifying zero or more free qubits and: (i) for each free qubit calculating said placement score, scaled by said constant factor; and (ii) reassigning said free qubits to improve said placement score; (c) calculating an edge score for each edge in said first level in said graph; (d) selecting an edge for inserting a SWAP gate using said edge score; (e) inserting said SWAP gate for said edge selected in (d); and (f) rebuilding said DAG at least in part by grouping executable gates into said first level. In some embodiments, wherein (a) and (b) are repeated until no executable gates are identified. In some embodiments, said edge score is one of said discounted edge score or said not discounted edge score. In some embodiments, if said edge score is said not discounted edge score edge score and two or more edge scores are identical, then the method further comprises using a decision tree mechanism at (d) to select said edge for inserting said SWAP gate.

In some embodiments, said decision tree mechanism comprises: (a) storing a copy of said output and a copy of said DAG; (b) ranking each edge of two or more edges with an identical highest immediate score, wherein said ranking comprises, until an end of a list of said two or more edges with said identical highest immediate score: (i) increasing a SWAP count by one for a next edge in said list of said two or more edges with said identical highest immediate score; (ii) inserting said SWAP gate for said next edge in said list of said two or more edges; (iii) rebuilding said DAG; (iv) until no gates remain in said first level of said DAG or until a rank of said next edge in said list of said two or more edges is calculated: (1) identifying said executable gates in said first level of said DAG and registering them to said output; (2) if one or more executable gates are identified in (1) identifying one or more free qubits and: (a) for each free qubit calculating said placement score; and (b) reassigning said free qubits to improve said placement score; (3) calculating a total edge score for each edge in said first level; (4) using said total edge score to select an edge for inserting said SWAP gate; (5) inserting said SWAP gate for said edge selected in (4) and increasing said SWAP count by one for a next edge in said list of said two or more edges; and (6) if said SWAP count exceeds a threshold number of SWAPs, calculating a current placement score for said vertices said graph to calculate a ranking of said vertices; if said SWAP count does not exceed said threshold number of SWAPs, rebuilding said DAG; (v) using said SWAP count to calculate said ranking of said next edge in said list of said two or more edges; and (vi) restoring said output representative of said routed circuit and DAG from said copy; and (c) comparing said rankings to select an edge for inserting said SWAP gate among said two or more edges with said identical highest immediate score.

In some embodiments, the method further comprises assigning commutable gates a same level in said DAG. In some embodiments, said quantum chip structure comprises superconducting physical qubits. In some embodiments, said quantum chip structure comprises ion trap physical qubits. In some embodiments, said graph representative of said quantum chip structure is a two-dimensional directed graph. In some embodiments, said graph representative of said quantum chip structure is a two-dimensional undirected graph.

In another aspect, the present disclosure provides a system for constructing a circuit to allocate information qubits, said circuit comprising one or more quantum gates. The system may comprise: (a) an intermediate communication interface comprising a controller configured to provide instructions to a quantum chip structure comprising physical qubits; and (b) a digital computer comprising a memory, said memory comprising instructions for constructing a routed circuit to allocate said information qubits on said quantum chip structure and for storing and providing an output representative of said routed circuit to said intermediate communication interface to be executed using said quantum chip structure.

In some embodiments, said digital computer is configured to: (a) obtain a list of two-qubit quantum gates, wherein said list comprises at least one two-qubit quantum gate; (b) use a graph representative of said quantum chip structure to implement a placement procedure on said list of said two-qubit quantum gates to obtain an initial placement of said information qubits on said quantum chip structure; (c) implement said a procedure to construct said routed circuit for said information qubits comprising said list of two-qubit quantum gates using said initial placement, wherein said routing procedure comprises a scoring system comprising discounted and not discounted scores; and (d) provide said output representative of said routed circuit, wherein said output comprises an order of execution of said one or more quantum gates, wherein said routed circuit is configured to allocate said information qubits on said quantum chip structure.

In some embodiments, said digital computer is further configured to construct at least one member of the group consisting of: a list of layers of said two-qubit quantum gates, an ordered list of said two-qubit quantum gates, and a dependency graph. In some embodiments, said dependency graph comprises a directed acyclic graph (DAG). In some embodiments, said digital computer is further configured to, until an end of a list of not-yet-executed quantum gates from said list of two-qubit quantum gates, assigning each gate a level on said DAG.

In some embodiments, said digital computer is further configured to provide said output representative of said routed circuit to an intermediate communication interface comprising a quantum chip controller to instruct said quantum chip structure to execute in the order of said provided output file representative of said routed circuit. In some embodiments, said graph comprises vertices and edges, and wherein said digital computer is further configured to calculate a placement score based at least in part on distances between said vertices of said graph, wherein said vertices each corresponds to an information qubit of said information qubits. In some embodiments, said distances between said vertices are scaled by a constant factor exponentiated by a level in said DAG of a two-qubit quantum gate.

In some embodiments, said digital computer is further configured to: (a) compute a Hamiltonian path of said quantum chip structure, wherein said Hamiltonian path is a path traversing said graph passing through each vertex of said graph once; and (b) use said Hamiltonian path to place said two-qubit quantum gates to obtain said initial placement. In some embodiments, said placement procedure comprises a randomized mixture of a greedy approach and a random approach. In some embodiments, said digital computer is further configured to implement said placement procedure a number of times and use said placement score to select said initial placement.

In some embodiments, said digital computer is further configured to, until no executable gates remain unevaluated in a first level of said DAG: (a) identify said executable gates in said first level of said DAG and registering them to said output representative of said routed circuit; (b) if one or more executable gates are identified in (a), then identify zero or more free qubits and: (i) for each free qubit calculate said placement score, scaled by said constant factor; and (ii) reassign said free qubits to improve said placement score; (c) calculate an edge score for each edge in said first level in said graph; (d) select an edge for inserting a SWAP gate using said edge score; (e) insert said SWAP gate for said edge selected in (d); and (f) rebuild said DAG at least in part by grouping executable gates into said first level. In some embodiments, said digital computer is further configured to repeat said obtaining said list and said using said graph until no executable gates are identified. In some embodiments, said edge score is one of said discounted edge score or said not discounted edge score. In some embodiments, if said edge score is said not discounted edge score edge score and two or more edge scores are identical, then said digital computer is further configured to use a decision tree mechanism to select said edge for inserting said SWAP gate.

In some embodiments, at said decision tree mechanism said digital computer is further configured to: (a) store a copy of said output and a copy of said DAG; (b) rank each edge of two or more edges with an identical highest immediate score, wherein said ranking comprises, until an end of a list of said two or more edges with said identical highest immediate score: (i) increase a SWAP count by one for a next edge in said list of said two or more edges with said identical highest immediate score; (ii) insert said SWAP gate for said next edge in said list of said two or more edges; (iii) rebuild said DAG; (iv) until no gates remain in said first level of said DAG or until a rank of said next edge in said list of said two or more edges is calculated: (1) identify said executable gates in said first level of said DAG and registering them to said output; (2) if one or more executable gates are identified in (1) identify one or more free qubits and: (A) for each free qubit calculate said placement score; and (B) reassign said free qubits to improve said placement score; (3) calculate a total edge score for each edge in said first level; (4) use said total edge score to select an edge for inserting said SWAP gate; (5) insert said SWAP gate for said edge selected in (4) and increasing said SWAP count by one for a next edge in said list of said two or more edges; and (6) if said SWAP count exceeds a threshold number of SWAPs, calculate a current placement score for said vertices said graph to calculate a ranking of said vertices; if said SWAP count does not exceed said threshold number of SWAPs, rebuilding said DAG; (v) use said SWAP count to calculate said ranking of said next edge in said list of said two or more edges; and (vi) restore said output representative of said routed circuit and DAG from said copy; and (c) compare said rankings to select an edge for inserting said SWAP gate among said two or more edges with said identical highest immediate score.

In some embodiments, said digital computer is further configured to assign commutable gates a same level in said DAG. In some embodiments, said quantum chip structure comprises superconducting physical qubits. In some embodiments, said quantum chip structure comprises ion trap physical qubits. In some embodiments, said graph representative of said quantum chip structure is a two-dimensional directed graph. In some embodiments, said graph representative of said quantum chip structure is a two-dimensional undirected graph. In some embodiments, said intermediate communication interface comprises one or more of a field-programmable gate array (FPGA) and an application-specific integrated circuit (ASIC). In some embodiments, said routed circuit is generated based at least in part on a routing procedure comprising a scoring system comprising discounted and not discounted scores.

In another aspect, the present disclosure provides a system for constructing a circuit to allocate information qubits on a quantum chip structure, wherein said circuit comprises one or more quantum gates. The system may comprise: (a) said quantum chip structure comprising physical qubits, wherein said quantum chip structure is a two-dimensional structure; (b) an intermediate communication interface comprising a controller to provide instructions to said quantum chip; and (c) a digital computer comprising memory comprising an application with instructions for constructing a routed circuit to allocate said information qubits on said quantum chip structure; and for storing and providing an output representative of said routed circuit to said intermediate communication interface to be executed using said quantum chip.

In some embodiments, said intermediate communication interface comprises one or more of a field-programmable gate array (FPGA) and an application-specific integrated circuit (ASIC). In some embodiments, said routed circuit is generated based at least in part on a routing procedure comprising a scoring system comprising discounted and not discounted scores.

In another aspect, the present disclosure provides a method for constructing a circuit to allocate information qubits, said circuit comprising one or more quantum gates. The method may comprise: (a) using a graph representative of a quantum chip structure to implement a placement procedure on a list of two-qubit quantum gates; (b) implementing a routing procedure to construct a routed circuit for said information qubits comprising said list of two-qubit quantum gates, wherein said routing procedure comprises a scoring system comprising discounted and not discounted scores; and (c) providing an output representative of said routed circuit, wherein said output comprises an order of execution of said one or more quantum gates.

In some embodiments, the method further comprises the method of any aspect or embodiment disclosed herein. In some embodiments, the method further comprises implementing said routed circuit on said quantum chip structure.

In another aspect, the present disclosure provides a method for constructing a routed circuit for allocating information qubits comprising at least one two-qubit gate and zero or more one-qubit gates on a quantum chip structure represented by a graph comprising vertices and edges. The method may comprise: (a) obtaining a list of two-qubit gates; (b) building a directed acyclic graph (DAG) comprising until the end of the list of not-yet-executed gates assigning to each gate a level on said DAG; (c) using the DAG to implement a placement procedure on said list of said two-qubit quantum gates to obtain an initial placement; (d) implementing a routing procedure to construct a routed circuit for the qubits comprising said two-qubit quantum gates using said obtained initial placement, wherein the routing procedure comprises a scoring system comprising discounted and not discounted scores; and (e) providing an output file representative of said routed circuit comprising the order of execution of said one- and two-qubit quantum gates.

In some embodiments, the method further comprises providing said output file representative of said routed circuit to an intermediate communication interface comprising a quantum chip controller to instruct said quantum chip to execute the gates in the order of said provided output file representative of said routed circuit. In some embodiments, (c) comprises calculating a placement score using the distance between the vertices of the corresponding qubits. In some embodiments, the distance between the vertices of the corresponding qubits is scaled by a constant factor exponentiated by the level in said DAG of the gate comprising said corresponding qubits. In some embodiments, the method further comprises: (1) computing a Hamiltonian path of said quantum chip, wherein said Hamiltonian path is a path traversing said graph passing through each vertex once; and (2) using said Hamiltonian path to place said two-qubit quantum gates to obtain initial placement. In some embodiments, (c) comprises a randomized mixture of a greedy approach and a random approach. In some embodiments, (c) comprises implementing said placement procedure a number of times and using said calculated scores to select said initial placement.

In some embodiments, (d) comprises until there are no gates in the first level: (1) identifying executable gates in said first level of said DAG and registering them to said output file representative of said routed circuit; and (2) if one or more executable gates are identified in (1) identifying free qubits and: (i) for each free qubit calculating score using the distance between the vertices of the corresponding qubits, scaled by a constant factor exponentiated by the level in said DAG of the gate comprising said corresponding qubits; (ii) reassigning said free qubits to improve said score; (A) calculating said edge score for each edge comprising said executable gates in said first level; (B) selecting an edge for inserting a SWAP gate using said calculated score; (C) inserting the SWAP gate for said selected edge; and (D) rebuilding said DAG comprising grouping said gates into said first level.

In some embodiments, (1) and (2) are repeated until no executable gates are identified. In some embodiments, said edge score is one of a discounted score and an immediate score. In some embodiments, if said edge score is an immediate score and two or more edge scores are identical, the method further comprises using a decision tree mechanism to select an edge for inserting a SWAP gate.

In some embodiments, said decision tree mechanism comprises: (1) storing a copy of said output file and a copy of said DAG; (2) ranking each edge of said two or more edges with said identical highest immediate score comprising until the end of the list of said two or more edges with said identical highest immediate score: (i) increasing SWAP count by one for a next edge in said list of said two or more edges with said identical highest immediate score; (ii) inserting SWAP gate for said next edge in said list; (iii) rebuilding said DAG; (iv) until no gates in the first level of said DAG or the rank of said next edge in said list is calculated: (A) identifying executable gates in said first level of said DAG and registering them to said output file; (B) if one or more executable gates are identified in (i) identifying free qubits and: a) for each free qubit calculating score using the distance between the vertices of the corresponding qubits; and b) reassigning said free qubits to improve said score to possibly create executable gates; (C) calculating a discounted edge score for each edge comprising gates in said first level; (D) using said calculated discounted edge score to select an edge for inserting a SWAP gate; (E) inserting the SWAP gate for said selected edge and increasing the SWAP count by one for said next edge in said list; (F) if the SWAP count exceeds pre-defined number of SWAPs, calculating the current placement score for said next edge in said list to calculate said ranking thereof; if SWAP count does not exceed pre-defined number of SWAPs, rebuilding said DAG; (v) using SWAP count to calculate said ranking of said next edge in said list; (vi) restoring output file representative of the routed circuit and DAG form said stored corresponding copies thereof; and (3) comparing said rankings to select an edge for inserting a SWAP gate among said two or more edges with said identical highest immediate score.

In some embodiments, wherein (b) further comprises assigning commutable gates the same level in said DAG. In some embodiments, said quantum chip comprises superconducting physical qubits. In some embodiments, said quantum chip comprises ion trap physical qubits. In some embodiments, said two-dimensional graph representative of said quantum chip is a directed graph. In some embodiments, said two-dimensional graph representative of said quantum chip structure is an undirected graph.

In another aspect, the present disclosure provides a system for allocating information qubits comprising one and two qubit gates on a quantum chip structure and for executing said gates on a quantum chip. The system may comprise: (a) a quantum chip comprising physical qubits; wherein said quantum chip structure is a two-dimensional structure; (b) an intermediate communication interface comprising a controller to provide instructions to said quantum chip; and (c) a digital computer comprising memory comprising an application with instructions for constructing a routed circuit to allocate information qubits comprising one and two qubit gates on a quantum chip structure; and for storing and providing output file representative of said routed circuit to said intermediate communication interface to be executed using said quantum chip.

In some embodiments, said intermediate communication interface comprises one or more of a field-programmable gate array (FPGA) and an application-specific integrated circuit (ASIC).

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 is a diagram of a system for constructing a routed circuit to allocate qubits on a quantum chip structure represented by a two-dimensional graph, in accordance with some embodiments disclosed herein.

FIG. 2 is a flowchart of a method for constructing a routed circuit to allocate qubits on a quantum chip structure represented by a two-dimensional graph, in accordance with some embodiments disclosed herein.

FIG. 3 is a flowchart of a routing procedure for constructing a routed circuit, in accordance with some embodiments disclosed herein.

FIG. 4 is a flowchart of a procedure for selecting an edge for inserting a SWAP gate, in accordance with some embodiments disclosed herein.

FIG. 5 is a flowchart of a procedure for ranking edges with an identical highest immediate edge score, in accordance with some embodiments disclosed herein.

FIG. 6 is an example of a two-dimensional graph representative of part of a quantum chip's structure wherein an immediate edge score is used, two or more edge scores are identical and the highest and there are two two-qubit quantum gates in the first level of a DAG consisting of four qubits which qubits are assigned to the vertices of the graph representative of the quantum chip structure satisfying the condition that the shortest distances between each pair of vertices share the same edge.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The technology disclosed in this patent document can be implemented in ways to provide a method and a system that can overcome the limitations associated with the quantum chip's structure and qubit allocation problem.

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

The term “plurality” generally refers to “two or more,” unless expressly specified otherwise.

The term “e.g.” and like terms mean “for example,” and thus do not limit the terms or phrases they explain. For example, in a sentence “the computer sends data (e.g., instructions, a data structure) over the Internet,” the term “e.g.” explains that “instructions” are an example of “data” that the computer may send over the Internet, and also explains that “a data structure” is an example of “data” that the computer may send over the Internet. However, both “instructions” and “a data structure” are merely examples of “data,” and other things besides “instructions” and “a data structure” can be “data.”

Where values are described as ranges, the disclosure includes the disclosure of all possible sub-ranges within such ranges, as well as specific numerical values that fall within such ranges irrespective of whether a specific numerical value or specific sub-range is expressly stated.

In the following detailed description, reference is made to the accompanying figures, which form a part hereof. In the figures, similar symbols typically identify similar components, unless context dictates otherwise. The illustrative embodiments described in the detailed description, figures, and claims are not meant to be limiting. Other embodiments may be used, and other changes may be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

Quantum computing generally refers to the method of computing which utilizes the concept of quantum superposition and entanglement to manipulate information, instead of the 0 and 1 binary bits in classical computers. Quantum entanglement generally refers to the phenomenon in which when multiple qubits interact with each other, their quantum states are “entangled” and may no longer be represented individually. Quantum superposition generally refers to the principle which states that the quantum state of a qubit can be represented by adding together two or more different quantum states, each associated with a probability. In some cases, the probabilities of all states add to 1. Quantum circuits, consisting of one or more quantum gates, may be designed to perform quantum computation, such as factoring large prime numbers, which may be infeasible or highly inefficient for classical computers. The term “quantum gates” generally refers to logical operators comprising one or multiple qubits, which can be used to perform logical operations. A “qubit,” short for “quantum bit,” generally refers to the basic unit of quantum information.

As used herein, the term “classical,” as used in the context of computing or computation, generally refers to computation performed using binary values using discrete bits without use of quantum mechanical superposition and quantum mechanical entanglement. A classical computer may be a digital computer, such as a computer employing discrete bits (e.g., 0's and 1's) without use of quantum mechanical superposition and quantum mechanical entanglement.

As used herein, the term “non-classical,” as used in the context of computing or computation, generally refers to any method or system for performing computational procedures outside of the paradigm of classical computing.

As used herein, the term “quantum device” generally refers to any device or system for performing computations using any quantum mechanical phenomenon such as quantum mechanical superposition and quantum mechanical entanglement.

As used herein, the terms “quantum computation,” “quantum procedure,” “quantum operation,” and “quantum computer” generally refer to any method or system for performing computations using quantum mechanical operations (such as unitary transformations or completely positive trace-preserving (CPTP) maps on quantum channels) on a Hilbert space represented by a quantum device

As used herein, the term “qubit” generally refers to a unit of quantum information processing whose quantum state is a complex unit vector of dimension 2. These two dimensions are typically referred to as “0” and “1.”

As used herein, the term “qudit” generally refers to a multi-level quantum system or to a qubit.

As used herein, the term “physical qubit” generally refers to a physical implementation of a qubit.

As used herein, the term “physical qudit” generally refers to a physical implementation of a qudit.

As used herein, the terms “SWAP” and “SWAP gate” generally refer to a two-qubit operation in which the states of the two qubits are exchanged.

As used herein, the term “graph” generally refers to a representation which comprises vertices (e.g., nodes) connected by edges.

As used herein, the term “directed acyclic graph (DAG)” generally refers to those graphs which have directed edges but no directed cycles.

As used herein, the terms “gates,” “two-qubit gates,” and “one-qubit gates” generally refer to quantum logic gates that consist of two qubits (“two-qubit gates”) or one qubit (“one-qubit gate”), and which are used to perform logical operations.

As used herein, the term “quantum chip” generally refers to a physical device that can utilize quantum phenomena that allows the execution of quantum gates for the purpose of computing.

As used herein, the term “circuit” generally refers to the representation of a computational model in which the computation is a sequence of gates. In some cases, a circuit may be used in gate model quantum computation. In some cases, a circuit may be a quantum circuit, such as a sequence of qubit gates used in a gate model quantum computation.

As used herein, the term “distance” used in relation to a graph may refer to the least number of edges connecting two vertices (nodes) on a graph or the shortest distance between two vertices (nodes) on a graph.

The information stored in physical qubits may, in some cases, be referred to simply as “qubits,” and the physical qubits and physical qudits on a quantum device as “vertices.”

Neither the Title nor the Abstract is to be taken as limiting in any way the scope of the disclosed invention(s). The title of the present application and headings of sections provided in the present application are for convenience only and are not to be taken as limiting the disclosure in any way.

In classical computers, information may be stored as bits. Similarly, in quantum computers, information is stored as “qubits” or “qudits.” There are various methods of realizing qubits and qudits using physical implementations. One method is via superconducting qubits and qudits, and another involves the use of ion trap qubits and qudits. Hereafter, when referring to “qubits” it should be assumed that what is described may also refer to “qudits.”

Though superconducting qubits may lend themselves well to manufacturing, they may limit how many neighboring qubits each qubit is connected to. In some cases, this may be limited to their nearest neighbors. Moreover, quantum computing devices with a large number of vertices may be hard to build. For example, quantum computing devices may be difficult to build because of engineering challenges or because quantum states may be fragile. A computation on a quantum computer may include operations on qubits, either directly on each one or by a joint operation between multiple qubits. For a joint operation between qubits, it may be advantageous that the qubits be capable of physically interacting with one another (e.g., physically interacting with one another with sufficient strength to perform a computation). In some cases, qubits capable of physically interacting with one another may be referred to as being “physically connected.” When the qubits are not physically connected, it may be advantageous to move the information stored in the qubits around in order make them capable of interacting with sufficient strength. The study of how to move the information around is sometimes referred to as the “qubit allocation problem.”

According to the no-cloning theorem in quantum mechanics (see Wootters et al., “The no-cloning theorem,” Physics Today 62, no. 2, pp. 76-77, 2009, which is incorporated herein by reference in its entirety), a perfect identical copy of an arbitrary unknown quantum state independent of the original quantum state cannot be created, which is incorporated herein by reference in its entirety. In order to avoid creating a copy, it may be useful to move quantum states around. Quantum states may be moved around using, for example, SWAP gates. In some cases, one or more SWAP gates may be inserted to swap the quantum states between two locations (e.g., two vertices) on the quantum chip.

In some cases, the action to move qubits around may be achieved via inserting a SWAP gate into the quantum circuit that is to be executed on the quantum computer. However, since inserting extra gates into a circuit may increase the length of the circuit and prolong the computation time, which may increase the likelihood of the accumulation of errors, it may be advantageous to devise a method which efficiently finds a reduced number of SWAP gates (e.g., a minimum) to insert in order to complete the computation of a circuit on a quantum computer.

In some cases, finding a reduced number of SWAP gates to solve a qubit allocation problem may be computationally expensive. For example, doing so may be an NP-complete problem; see Siraichi et al., “Qubit allocation,” in Proceedings of the 2018 International Symposium on Code Generation and Optimization, pp. 113-125, 2018, which is incorporated herein by reference in its entirety. For example, methods such as “Tackling the Qubit Mapping Problem for NISQ-Era Quantum Devices” by Li et al., arXiv:1809.02573, 2018 and “On the qubit routing problem” by Cowtan et al., arXiv:1902.08091, 2019, each of which is incorporated herein by reference in its entirety, may use heuristic methods that have drawbacks, which include but are not limited to performing an exhaustive search of all possible solutions, not utilizing the concept of gate commutation, having an expensive search space when locating the best edges to insert SWAP gates, and having a static DAG layer concept.

Some existing solutions relevant to our approach are based on the observation that the placement and routing problem may be an inherently temporal problem over the span of multiple decision epochs. This may include an exact, but exponentially computationally expensive, dynamic programming solution (Siraichi et al., “Qubit allocation,” in Proceedings of the 2018 International Symposium on Code Generation and Optimization, pp. 113-125, 2018, which is incorporated herein by reference in its entirety), temporal planning and constraint programming (Booth et al., “Comparing and Integrating Constraint Programming and Temporal Planning for Quantum Circuit Compilation,” ICAPS, 2018, each of which is incorporated herein by reference in its entirety), and methods that use reinforcement learning (Herbert et al., “Using Reinforcement Learning to Find Efficient Qubit Routing Policies for Deployment in Near-term Quantum Computers,” arXiv:1812.11619, 2018; Sinha et al., “Qubit Routing using Graph Neural Network aided Monte Carlo Tree Search,” arXiv:2104.01992, 2021, each of which is incorporated herein by reference in its entirety). On one hand, these approaches are superior to the greedy techniques that neglect the future impact of decisions made at earlier decision epochs. On the other hand, the global nature of the optimization problem solved may hinder the scalability of the algorithm, especially in instances where the compilation procedure is expected to include computationally intensive subroutines such as the training of neural networks.

The present disclosure provides methods and systems for implementing a series of operations on a quantum computer. Methods and systems of the present disclosure may be implemented as a computer-implemented method. Methods and systems of the present disclosure may provide at least two procedures: a placement procedure and a routing procedure.

In some cases, a placement procedure as disclosed herein computes and compares various options of where to place the qubits on a quantum chip, and by choosing an improved option based on the procedure selection criteria, the procedure may produce an initial mapping of the qubits. The initial mapping may refer to a map of where each qubit is assigned to be stored on a physical quantum chip during an initial phase of the computation. In some cases, the routing procedure may direct where and how the qubits are moved to meet their neighboring qubits in order to execute the quantum circuit. The route may be represented by indicating where the SWAP gates are inserted.

Methods and systems disclosed herein may be implemented to provide an end-to-end system for the qubit allocation problem. The system may comprise a classical digital computer, an intermediate communication interface, and a quantum computing device. The present disclosure may improve upon existing optimization solvers in at least some aspects. For example, the methods and systems disclosed herein may provide a routed circuit with a reduced number of SWAP gates (e.g., a minimum). The disclosed methods and systems may take advantage of the concept of quantum gate commutation, identify commutable gates, and dynamically compute the DAG at each processing operation. Methods and systems disclosed herein may allow the gates to be executed not necessarily in the same order as they appear in the quantum circuit. Dynamically computed DAG and gate commutation may allow for more gates to be executed each time the procedure checks for executable gates, thus resulting in a lower SWAP gate count.

Another advantage of the methods and systems disclosed herein may include taking advantage of scoring systems. Having scoring systems in place may allow the procedures to determine the impact on the SWAP gate count of different operations performed and adjust the strategy for every next move accordingly. For example, an initial placement score mechanism may ensure that the placement that leads to the lowest (e.g., most improved) score may be used. For example, an edge score mechanism may allow the routing procedure to measure the impact of potential SWAP gates that may be inserted at a later time. The scoring system may take advantage of the proposed DAG level mechanism and may scale the scores according to the level of the gate on the DAG, which emphasizes the importance of the gates that are assigned a level closer to the first level of the DAG.

Another advantage of the disclosed technology may include the decision tree mechanism which is a part of the routing procedure. Assigning edge scores based on the distances between target vertices may lead to tie scores on smaller quantum chip structures. The proposed decision tree may act as a “look into the future,” allowing the procedure to measure the impact of potentially inserting SWAP gates on different edges without actually inserting the SWAP gates in the routed circuit.

Another advantage of the technology disclosed herein may include the use of an ensemble of various algorithms for a placement procedure. According to various publications such as Siraichi et al., “Qubit allocation,” in Proceedings of the 2018 International Symposium on Code Generation and Optimization, pp. 113-125, 2018 and Zulehner et al., “An efficient methodology for mapping quantum circuits to the IBM QX architectures,” IEEE Transactions on Computer-Aided Design of Integrated Circuits and Systems 38, no. 7, pp. 1226-1236, 2018, each of which is incorporated herein by reference in its entirety, an initial placement may have a significant effect on the routing results. Having an ensemble of different algorithms may allow for combinations of different strategies to carry out the initial placement. Along with the scoring system, a combination of strategies may increase the likelihood that the procedure may find a feasible method for initial placement for various types of circuits to carry out the computation, since different types of circuits might benefit from different placement strategies.

Another advantage of the technology disclosed herein may include the free-qubit mechanism. Having a mechanism to handle free qubits may be beneficial when there are large amounts of qubits in the circuit. At the start of the routing procedure, in some cases, there may be a large portion of the placed qubits which have not yet been executed. At this stage, the placement of the not-yet-executed free qubits may be allowed to be changed without inserting SWAP gates, which may lead to a lower overall number of SWAP gates used.

Another advantage of the methods and systems disclosed herein may be that the procedure's parameters, such as the pre-defined number of SWAP gates used in the decision tree mechanism and the constant used to scale the placement scores, may be tuned by a user. Different circuits may benefit from different values of parameters. For example, a tunable parameter may allow for improved performance for different types of circuits.

Yet another advantage of the disclosed methods may be that various types of quantum chip architectures may be supported, such as the structures represented by directed and undirected graphs. Architectures represented by directed graphs may have a constraint such as that quantum gates consisting of two qubits can be executed when the corresponding qubits are placed adjacent to each other in a specific orientation, according to the direction of the edge in the directed graph. The routing procedure disclosed herein may perform routing on both directed and undirected graphs.

### Multi-Level Quantum System

A multi-level quantum system may be structured in a way which operates based on quantum mechanical processes such as superposition and entanglement of quantum states. A multi-level system can include a system with two or more energy states of an artificial or natural atom, for example, the ground (10>) and first excited state (11>) of a superconducting artificial atom. Such a multi-level system can have 0, 1, . . . , n energy states. A multi-level quantum system may be referred to as a “qudit” and multiple qudits may be used to implement a quantum computing system. A qudit may be thought of as one of n quantum states 0, 1, . . . , n−1 or a superposition of any of the n states. Specific subcategories of qudits exist, including a system consisting of two energy states, the ground state (|0>) and first excited state (|1>). These two-state systems are referred to as “qubits.” Each qubit can be placed in one of these two states. However, due to the nature of multi-level quantum systems, they can also be placed in a superposition of these two states. Entangled qubit or qudit devices can perform computational tasks.

### NISQ—Noisy Intermediate-Scale Quantum Technology

The term “noisy, intermediate-scale quantum” (NISQ) was introduced by John Preskill in “Quantum Computing in the NISQ era and beyond,” arXiv:1801.00862, 2018, which is incorporated herein by reference in its entirety. Here, the term “noisy” implies that we have incomplete control over the qubits and “intermediate-scale” refers to the number of qubits which may range from 50 to a few hundred. Several physical systems made from superconducting qubits, artificial atoms, or ion traps have been proposed so far as feasible candidates to build NISQ devices and ultimately universal quantum computers.

Methods and systems disclosed herein may be suitable for a NISQ device. In some cases, a NISQ device with a limitation of a two-dimensional structure of a quantum chip or a limitation on how many neighboring qubits (or qudits) each qubit (or qudit) is connected to may benefit from methods and systems disclosed herein.

### Quantum Device

Any type of non-classical computer, for example, a quantum computer, may be suitable for the technologies disclosed herein. In some cases, a quantum device with a limitation of a two-dimensional structure of a quantum chip or a limitation on how many neighboring qubits (or qudits) each qubit (or qudit) is connected to may benefit from methods and systems disclosed herein. In accordance with the description herein, suitable quantum computers may include, by way of non-limiting examples: superconducting quantum computers (qubits implemented as small superconducting circuits—Josephson junctions) (Clarke et al., “Superconducting quantum bits,” Nature 453, no. 7198, pp. 1031-1042, 2008); trapped-ion quantum computers (qubits implemented as states of trapped ions) (Kielpinski et al., “Architecture for a large-scale ion-trap quantum computer,” Nature 417, no. 6890, pp. 709-711, 2002); optical lattice quantum computers (qubits implemented as states of neutral atoms trapped in an optical lattice) (Deutsch et al., “Quantum computing with neutral atoms in an optical lattice,” Fortschritte der Physik: Progress of Physics 48, no. 9-11, pp. 925-943, 2000); spin-based quantum dot computers (qubits implemented as the spin states of trapped electrons) (Imamoglu et al., “Quantum information processing using quantum dot spins and cavity QED,” Physical Review Letters 83, no. 20, p. 4204, 1999); spatial-based quantum dot computers (qubits implemented as electron positions in a double quantum dot) (Fedichkin et al., “Novel coherent quantum bit using spatial quantization levels in semiconductor quantum dot,” arXiv:quant-ph/0006097, 2000); coupled quantum wires (qubits implemented as pairs of quantum wires coupled by quantum point contact) (Bertoni et al., “Quantum logic gates based on coherent electron transport in quantum wires,” Physical Review Letters 84, no. 25, p. 5912, 2000); nuclear magnetic resonance quantum computers (qubits implemented as nuclear spins and probed by radio waves) (Cory et al., “Nuclear magnetic resonance spectroscopy: An experimentally accessible paradigm for quantum computing,” arXiv:quant-ph/9709001, 1997); solid-state NMR Kane quantum computers (qubits implemented as the nuclear spin states of phosphorus donors in silicon) (Kane, “A silicon-based nuclear spin quantum computer,” Nature 393, no. 6681, pp. 133-137, 1998); electrons-on-helium quantum computers (qubits implemented as electron spins) (Lyon, “Spin-based quantum computing using electrons on liquid helium,” arXiv:cond-mat/0301581, 2006); molecular magnet-based quantum computers (qubits implemented as spin states) (Leuenberger et al., “Quantum Computing in Molecular Magnets,” arXiv:cond-mat/0011415, 2001); fullerene-based ESR quantum computers (qubits implemented as electronic spins of atoms or molecules encased in fullerenes) (Harneit, “Spin Quantum Computing with Endohedral Fullerenes,” arXiv:1708.09298, 2017); diamond-based quantum computers (qubits implemented as electronic or nuclear spins of nitrogen-vacancy centres in diamond) (Nizovtsev et al., “A quantum computer based on NV centers in diamond: optically detected nutations of single electron and nuclear spins,” Optics and spectroscopy 99, no. 2, pp. 233-244, 2005); Bose—Einstein condensate-based quantum computers (qubits implemented as two-component BECs) (Byrnes et al., “Macroscopic quantum computation using Bose—Einstein condensates,” arXiv:quantum-ph/1103.5512, 2011); transistor-based quantum computers (qubits implemented as semiconductors coupled to nanophotonic cavities) (Sun et al., “A single-photon switch and transistor enabled by a solid-state quantum memory,” arXiv:quant-ph/1805.01964, 2018); metal-like carbon nanospheres based quantum computers (qubits implemented as electron spins in conducting carbon nanospheres) (Wrath et al., “Room temperature manipulation of long lifetime spins in metallic-like carbon nanospheres,” arXiv:cond-mat/1611.07690, 2016); each of which is incorporated herein by reference in its entirety.

Methods and systems disclosed herein may be suitable for a device which simulates a quantum computer. For example, methods and systems disclosed herein may be suitable for a device which exploits quantum mechanical properties, but which comprises a limited number of gate operations or which does not implement a series of qubit gate operations. In some cases, a device which simulates a quantum computer with a limitation of a two-dimensional structure of a quantum chip or a limitation on how many neighboring qubits (or qudits) each qubit (or qudit) is connected to may benefit from methods and systems disclosed herein.

### Digital Computer

In some cases, the digital computer comprises one or more hardware central processing units (CPUs) that carry out the digital computer's functions. In some cases, the digital computer further comprises an operating system (OS) configured to perform executable instructions. In some cases, the digital computer is connected to a computer network. In some cases, the digital computer is connected to the Internet such that it accesses the World Wide Web. In some cases, the digital computer is connected to a cloud computing infrastructure. In some cases, the digital computer is connected to an intranet. In some cases, the digital computer is connected to a data storage device.

In accordance with the description herein, suitable digital computers may include, by way of non-limiting examples, server computers, desktop computers, laptop computers, notebook computers, sub-notebook computers, netbook computers, netpad computers, set-top computers, media streaming devices, handheld computers, Internet appliances, mobile smartphones, tablet computers, personal digital assistants, video game consoles, and vehicles. Smartphones may be suitable for use in some cases of the method and the system described herein. Select televisions, video players, and digital music players, in some cases with computer network connectivity, may be suitable for use with one or more variations, examples, or embodiments of the systems and the methods described herein. Suitable tablet computers may include those with booklet, slate, and convertible configurations.

In some cases, the digital computer comprises an operating system configured to perform executable instructions. The operating system may be, for example, software, comprising programs and data, which manages the device's hardware and provides services for execution of applications. Suitable server operating systems include, by way of non-limiting examples, FreeBSD, OpenBSD, NetBSD®, Linux, Apple® Mac OS X Server®, Oracle® Solaris®, Windows Server®, and Novell® NetWare®. Suitable personal computer operating systems may include, by way of non-limiting examples, Microsoft® Windows®, Apple® Mac OS X®, UNIX®, and UNIX-like operating systems such as GNU/Linux®. In some cases, the operating system is provided by cloud computing. Suitable mobile smart phone operating systems may include, by way of non-limiting examples, Nokia® Symbian® OS, Apple® iOS®, Research In Motion® BlackBerry OS®, Google® Android®, Microsoft® Windows Phone® OS, Microsoft® Windows Mobile® OS, Linux®, and Palm® WebOS®. Suitable media streaming device operating systems may include, by way of non-limiting examples, Apple TV®, Rokut, Boxee®, Google TV®, Google Chromecast®, Amazon Fire®, and Samsung® HomeSync®. Suitable video game console operating systems may include, by way of non-limiting examples, Sony® Mt, Sony® PS4®, Microsoft® Xbox 360®, Microsoft® Xbox One®, Nintendo® Wii®, Nintendo® Wii U®, and Ouya®.

In some cases, the digital computer comprises a storage and/or memory device. In some cases, the storage and/or memory device is one or more physical apparatuses used to store data or programs on a temporary or permanent basis. In some cases, the device comprises a volatile memory and requires power to maintain stored information. In some cases, the device comprises non-volatile memory and retains stored information when the digital computer is not powered. In some cases, the non-volatile memory comprises a flash memory. In some cases, the non-volatile memory comprises a dynamic random-access memory (DRAM). In some cases, the non-volatile memory comprises a ferroelectric random-access memory (FRAM). In some cases, the non-volatile memory comprises a phase-change random-access memory (PRAM). In some cases, the device comprises a storage device including, by way of non-limiting examples, CD-ROMs, DVDs, flash memory devices, magnetic disk drives, magnetic tapes drives, optical disk drives, and cloud computing based storage. In some cases, the storage and/or memory device comprises a combination of devices, such as those disclosed herein.

In some cases, the digital computer comprises a display used for providing visual information to a user. In some cases, the display comprises a cathode ray tube (CRT). In some cases, the display comprises a liquid crystal display (LCD). In some cases, the display comprises a thin film transistor liquid crystal display (TFT-LCD). In some cases, the display comprises an organic light-emitting diode (OLED) display. In some cases, an OLED display comprises a passive-matrix OLED (PMOLED) or active-matrix OLED (AMOLED) display. In some cases, the display comprises a plasma display. In some cases, the display comprises a video projector. In some cases, the display comprises a combination of devices, such as those disclosed herein.

In some cases, the digital computer comprises an input device to receive information from a user. In some cases, the input device comprises a keyboard. In some cases, the input device comprises a pointing device including, by way of non-limiting examples, a mouse, trackball, trackpad, joystick, game controller, or stylus. In some cases, the input device comprises a touch screen or a multi-touch screen. In some cases, the input device comprises a microphone to capture voice or other sound input. In some cases, the input device comprises a video camera or other sensor to capture motion or visual input. In some cases, the input device comprises a Kinect, Leap Motion, or the like. In some cases, the input device comprises a combination of devices, such as those disclosed herein.

### Quantum Gates

Single-qubit (or one-qubit) quantum gates may be of various types such as the Pauli-X gate, the Pauli-Y gate, the Pauli-Z gate, the Hadamard gate, the rotation gates, the identity gate, and the T-gate.

Two-qubit quantum gates may be of various types such as the CNOT gate and the SWAP gate. The CNOT gate may comprise two qubits, with a logical operation being flipping the second qubit (the target qubit) if and only if the first qubit (the control qubit) is |1>. The SWAP gate may comprise a two-qubit logical operation of swapping the states of the two qubits.

### Graph Representative of Quantum Chip Structure

Graphs are used to represent the physical quantum chip structure. Each physical qubit may be represented as a vertex in the graph and the connection between physical qubits is represented by edges between vertices. For devices which do not impose directional constraints on gates, the quantum chip structure may be represented as an undirected graph. For devices that do have a directional constraint, the quantum chip structure may be represented as a directed graph. The graphs are represented using adjacency matrices.

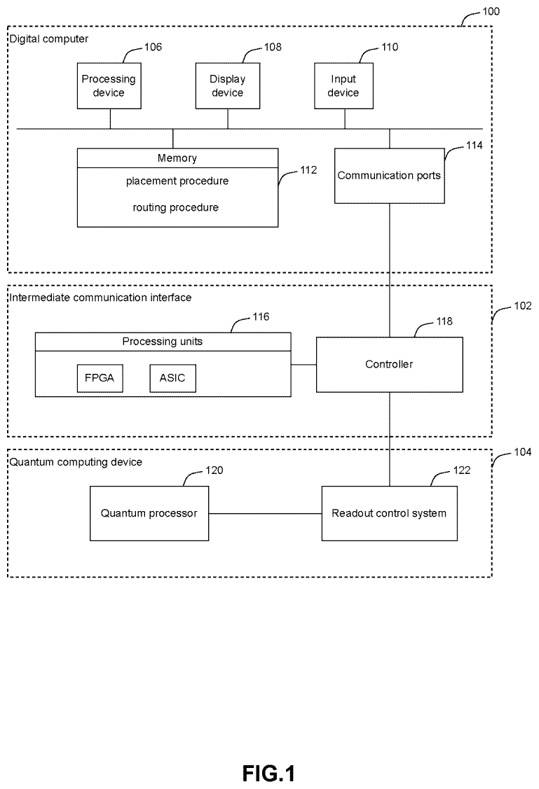

Now referring to FIG. 1, there is shown a diagram of a system for constructing a routed circuit to allocate qubits on a quantum chip structure represented by a two-dimensional graph. The system comprises a digital computer 100 comprising at least one processing device 106, a display device 108, an input device 110, and a memory 112 comprising a computer program executable by the processing device comprising instructions for constructing a routed circuit to allocate qubits comprising one- and two-qubit gates on a quantum chip structure and for storing and providing an output file representative of the routed circuit to an intermediate communication interface to be executed using a quantum chip. The instructions may further comprise a placement procedure and a routing procedure implementation. In some cases, the digital computer 100 may be of various types, such as any digital computer disclosed herein.

The system further comprises an intermediate communication interface 102 comprising one or more processing units 116 and a controller 118 to communicate with a quantum computing device 104. The communication may comprise providing the quantum chip with instructions comprising the routed circuit. In some cases, the processing unit 116 comprises a field-programmable gate array (FPGA). In some cases, the processing unit 116 comprises an application-specific integrated circuit (ASIC).

Still referring to FIG. 1, the system may further comprise a quantum computing device 104 comprising a quantum processor 120 comprising a quantum chip. The quantum chip comprises physical qubits. The quantum chip structure is a two-dimensional structure with a limitation on the number of neighboring qubits. In some cases, the quantum chip comprises physical qudits. In some cases, the quantum computing device comprises a readout control system 122 for quantum measurement readouts.

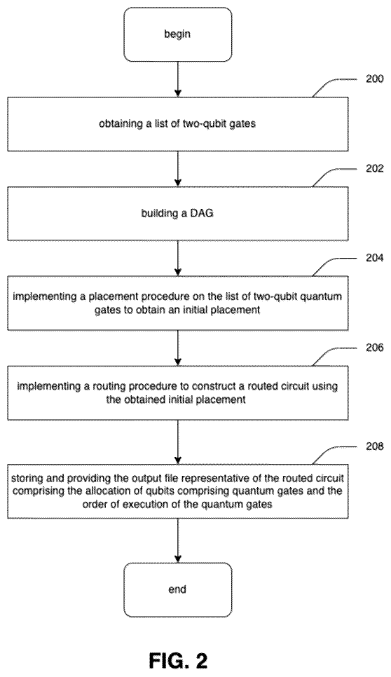

FIG. 2 is a flowchart of a method for constructing a routed circuit to allocate qubits on a quantum chip structure represented by a two-dimensional graph. In some cases, the two-dimensional graph comprises vertices and edges representing the quantum chip's physical qubits and connections thereof. The qubits may comprise one-qubit gates and two-qubit gates comprising a quantum circuit. A quantum circuit may be represented as a list of tuples wherein an n-tuple denotes a sequence of n elements. Quantum gates consisting of one qubit are represented by a 1-tuple and those consisting of two qubits are represented by a 2-tuple.

According to processing operation 200, a list of two-qubit gates is obtained. To obtain the list of two-qubit gates, the method iterates through the list of all quantum gates and filters out the 1-tuple entries. In some cases, gates with two qubits are considered for initial placement due to the fact that for those gates, the corresponding placement of the qubits on the vertices of the two-dimensional graph representative of the quantum chip structure may be adjacent to each other on the quantum chip in order to be executed, while quantum gates consisting of one qubit do not have such constraints.

Still referring to FIG. 2 and according to processing operation 202, a DAG is built. Building the DAG comprises iterating through the list of not-yet-executed two-qubit gates and assigning each such gate a level on said DAG. More precisely, the method parses the entire quantum circuit in a sequential manner and builds a DAG based on the relations between the qubits indicated by the quantum gates. To build the DAG, the method keeps track of the not-yet-executed two-qubit quantum gates and assigns each quantum gate a level on the DAG.

In quantum computing, a quantum gate can be mathematically represented by a matrix. Two quantum gates commute with each other if their respective matrices commute with each other. If two matrices commute, mathematically the product of the two matrices produces the same results regardless of the order of multiplication of the matrices. Two or more gates trivially commute if they do not share the same qubit. For non-commutable gates, each gate may be assigned its own level. The method may iterate through the list of not-yet-executed quantum gates. For a next not-yet-executed quantum gate in the list the method may identify the gates with the highest level assigned and comprising at least one of the qubits of the next not-yet-executed quantum gate. The next not-yet-executed quantum gate may be assigned a level which is a maximal level of the level of the identified gates, if the next not-yet-executed quantum gate commutes with all the identified gates having the maximal level. The next not-yet-executed quantum gate may be assigned a level which is a maximal level of the levels of the identified gates increased by one, if the next not-yet-executed quantum gate does not commute with at least one identified gate having the maximal level.

In some implementations, processing operation 202 is omitted. In some implementations, processing operation 202 is replaced by constructing an ordered list of layers of the two-qubit gates. In some cases, processing operation 202 is replaced by constructing an ordered list of two-qubit gates. In some cases, processing operation 202 is replaced by constructing a dependency graph different from the DAG.

Still referring to FIG. 2 and according to processing operation 204, a placement procedure is implemented on the list of two-qubit quantum gates to obtain an initial placement. The placement procedure may be implemented using the DAG. In some implementations, the placement procedure may be implemented using the obtained list of two-qubit gates, the constructed ordered list of two-qubit gates, the constructed ordered list of layers of the two-qubit gates, or the constructed dependency graph.

In some cases, an improved initial placement leads to fewer SWAP gates being required to route the circuit. The initial placement strategy may be a randomized mixture of a greedy approach and a random approach, with a pre-defined probability of using either approach. The pre-defined probability may be any probability between zero and one. The random approach comprises a random uniform initial placement. The greedy approach iterates through the list of all two-qubit quantum gates in the circuit. The corresponding qubits of the gates are stored according to the order they appear. After iterating through each of the qubits in the circuit a pre-defined number of times, the ordered list of qubits is placed according to the pre-computed Hamiltonian path of the quantum chip's structure. The rest of the not-yet-placed qubits from one-qubit quantum gates are then placed onto empty vertices of the Hamiltonian path, following the already placed two-qubit quantum gate's vertices. Since the quantum chip's structure can be represented as either a directed or an undirected graph depending on the structure of the quantum chip used, the Hamiltonian path is simply a path traversing the graph which passes through each vertex exactly once. If the structure does not contain a Hamiltonian path, a longest path within the graph representing the structure may be constructed. Depending on the number of vertices contained in the longest path, the corresponding number of qubits are assigned to the vertices in the path according to the order the qubits appear in the circuit. In some cases where the number of qubits in the circuit is larger than the number of vertices in the longest path, the remaining qubits may be assigned to the remaining vertices of the structure randomly. In some cases, initial placement has a significant impact on the SWAP gate count. Consequently, introducing randomness with the two aforementioned approaches allows for a greater probability of encountering a good initial placement. The aforementioned initial placement procedure may be run multiple times, but the one which yields the best (e.g., lowest) initial placement score is used.

In some cases, there are more vertices in the quantum device than there are qubits in the circuit. The initial placement may result in non-contiguous qubit placement on the quantum chip. The placement procedure disclosed herein moves the qubits toward the center of the quantum chip's structure, which enables the corresponding qubits of the quantum gates that appear early in the circuit to be placed adjacent to each other, allowing a quantum gate to be executed at the beginning of the method without inserting a SWAP gate.

To determine the impact of initial placement on the SWAP count, a scoring system may be used. For each two-qubit quantum gate, the placement score may be given by the distance between the vertices of the corresponding qubits, scaled by a constant factor which is exponentiated by the level of the gate on the DAG. The constant factor may be any number between 0 and 1 inclusive. In some cases, an edge score may relate to a distance, scaled by a constant factor which is exponentiated by a level of the gate on the DAG similarly to a placement score. It is adjustable in order to achieve optimal performance for different types of circuits. A lower score indicates a closer initial placement of corresponding qubits of the quantum gates. Placing the qubits which belong to the same quantum gate closer to each other allows the gates which appear early in the circuit to be executed; thus, a SWAP gate may not be inserted at the start of the method. A lower score therefore may indicate a better initial placement.

Still referring to FIG. 2 and according to processing operation 206, a routing procedure is implemented to construct a routed circuit using the obtained initial placement. The routing procedure comprises a scoring system including discounted and not discounted scores. In some cases, a not discounted score may be referred to herein as an immediate score. In some implementations wherein the constructed ordered list of two-qubit gates is used, the routing procedure may include using a heuristic algorithm which takes the impact of the next-to-be-executed gates into account. In some implementations wherein the constructed ordered list of layers of the two-qubit gates is used, the routing procedure may include going through each layer in a static fashion and not modifying the layers as the routing procedure progresses. In some implementations wherein the constructed dependency graph is used, the routing procedure may include utilizing the dependency graph to choose the next-to-be-routed gates.

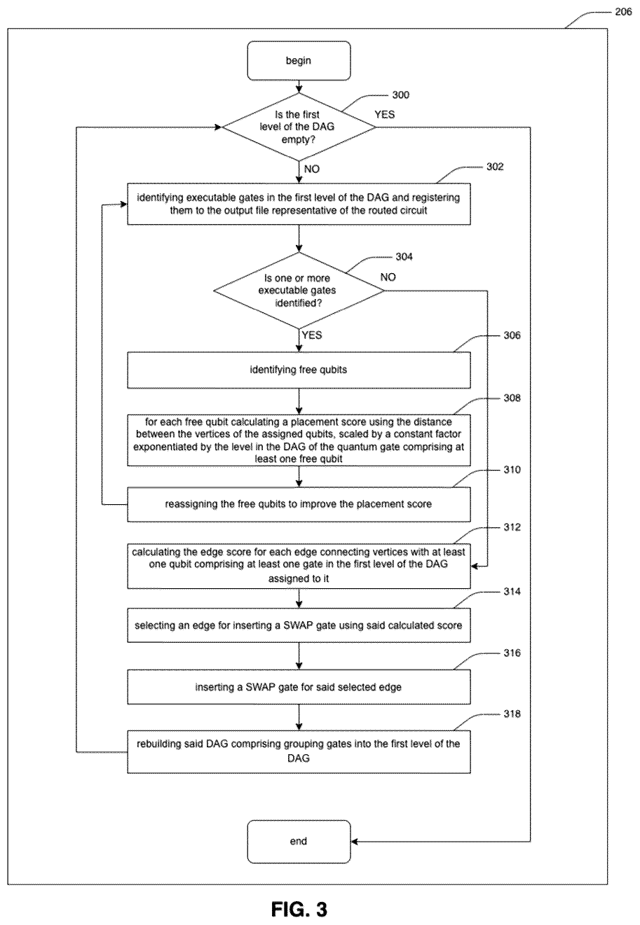

Now referring to FIG. 3, there is shown is a flowchart of a routing procedure for constructing a routed circuit using the obtained initial placement and using the DAG.

According to processing operation 300, if the first level of the DAG is empty then the routing procedure is terminated as all quantum gates in the circuit have been processed; if there is at least one quantum gate in the first level of the DAG, then according to processing operation 302, the executable quantum gates in the first level of the DAG are identified and registered to the output file representative of the routed circuit. In some cases, a two-qubit quantum gate in the first level is considered to be executable if the two qubits comprising the gate are assigned to neighboring vertices. Once a quantum gate is identified and registered to the output file representative of the routed circuit, it is removed entirely from the DAG. Subsequently, the method looks for the next executable quantum gate in the DAG. A one-qubit quantum gate in the first level is always considered to be executable. During the process of searching for executable quantum gates, in some cases wherein there are more vertices in a graph representative of a quantum chip than there are qubits to be placed in the quantum circuit, there may be unoccupied vertices in the graph representative of the quantum chip. In such cases, if a qubit has not yet been used in any quantum gate registered in the output file representative of the routed circuit, it is free to be reassigned to a different vertex. These yet-to-be-executed qubits are referred to as “free qubits.”

Still referring to FIG. 3 and according to processing operation 304, if one or more executable gates were identified in processing operation 302, then according to processing operation 306 free qubits are identified. If no executable gates were identified in processing operation 302, then the procedure moves to processing operation 312.

According to processing operation 308, for each free qubit identified in processing operation 306 a placement score is calculated. For each two-qubit quantum gate comprising at least one free qubit, the placement score is calculated using the graph distance between the vertices of the corresponding qubits, scaled by a constant factor which is exponentiated by the level of the two-qubit quantum gate in the DAG comprising at least one free qubit. The constant factor may be any number between 0 and 1 inclusive. It is adjustable in order to achieve optimal performance for different types of circuits. A lower score indicates a closer placement of corresponding qubits of the quantum gates. A lower score therefore indicates a better placement. The placement score is calculated to check if moving the free qubits from their designated vertices to a proposed one may lower the total graph distance. If it is so, according to processing operation 310, the free qubits are reassigned to new vertices to improve the placement score. If at least one free qubit is reassigned the procedure returns to processing operation 302.

Still referring to FIG. 3 and according to processing operation 312, for each edge connecting vertices that have at least one vertex assigned to a qubit comprising at least one quantum gate in the first level of the DAG the edge score is calculated. For each edge under consideration the qubits assigned to the vertices connected by the edge are identified. At least one of the two identified qubits is a qubit comprising a quantum gate in the first level of the DAG. If a qubit comprises more than one quantum gate in the first level of the DAG, then the first such quantum gate in the first level is considered. Such a qubit is referred to as an “active qubit” and the vertex it is assigned to is referred to as an “active vertex.” The other qubit is referred to as an “inactive qubit” and the vertex the inactive qubit is assigned to is referred as an “inactive vertex.” The quantum two-qubit gate comprising an active qubit is then considered for an edge score calculation. The second qubit comprising the same two-qubit quantum gate is identified. In some cases, the inactive qubit and the second qubit identified while considering an edge may be different qubits, and the inactive vertex and the vertex the second qubit is assigned to may be different vertices. The immediate score of the edge under consideration is calculated using the graph distance between the active vertex and the vertex the second qubit is assigned to minus the graph distance between the inactive vertex and the vertex the second qubit is assigned to.

The “discounted edge score” of the edge under consideration is calculated using all or a pre-defined number of the quantum gates in the first level and in the other levels of the DAG which comprise at least one of the two qubits assigned to the vertices at the ends of the edge under consideration. In the case of the discounted edge score the difference in the distances is scaled by a constant factor between 0 and 1, which is exponentiated by the level of the gate in the DAG. When the level of the gate is 0, we have an immediate edge score. In some cases, a high immediate or discounted edge score indicates a large reduction in distance if the SWAP gate is inserted for the edge, meaning the qubits belonging to the same gate are moved closer to each other.

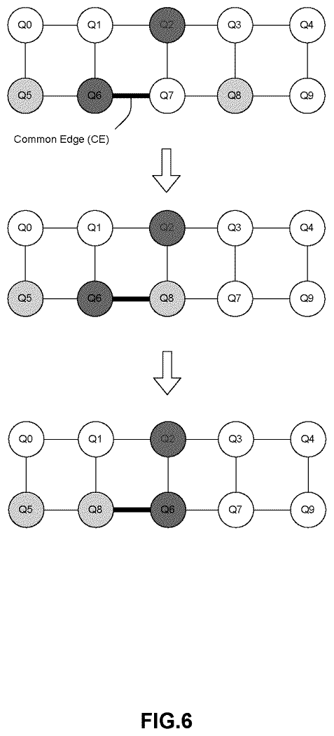

Still referring to FIG. 3 and according to processing operation 314, an edge for inserting the SWAP gate is selected using the edge score calculated in processing operation 312. In some cases, any of a discounted or an immediate edge score may be used. The edge with the highest edge score is selected. If the edge score is used in processing operation 312 and two or more edge scores are identical and, moreover, there are two two-qubit quantum gates in the first level consisting of four qubits which qubits are assigned to the vertices of the graph representative of the quantum chip structure satisfying the condition that the shortest distances between each pair of vertices share the same edge, the common edge is selected. In some cases, a SWAP gate is inserted to bring one of the aforementioned four qubits to one end of the common edge such that both two-qubit quantum gates can be made executable with one additional swap after such operation. Now referring to FIG. 6, if a SWAP gate is inserted between (Q8, Q7), then one additional SWAP gate between (Q8, Q6) can make both (Q2, Q6) and (Q5, Q8) executable.

According to processing operation 316, a SWAP gate is inserted for the selected edge.

According to processing operation 318, the DAG is rebuilt taking into consideration the inserted SWAP gate, in particular, grouping gates into the first level of the DAG.

Now referring back to FIG. 2 and according to processing operation 208, the output file representative of the routed circuit is stored and provided. The routed circuit comprises the allocation of qubits comprising one- and two-qubit quantum gates on a quantum chip structure and the order of execution of the one- and two-qubit quantum gates. In some cases, the output file representative of the routed circuit is provided to an intermediate communication interface. The intermediate communication interface may be of various types such as any type disclosed herein with respect to FIG. 1. The intermediate communication interface may comprise a quantum chip controller to instruct the quantum chip to execute the quantum gates in the order indicated in the provided output file representative of the routed circuit.

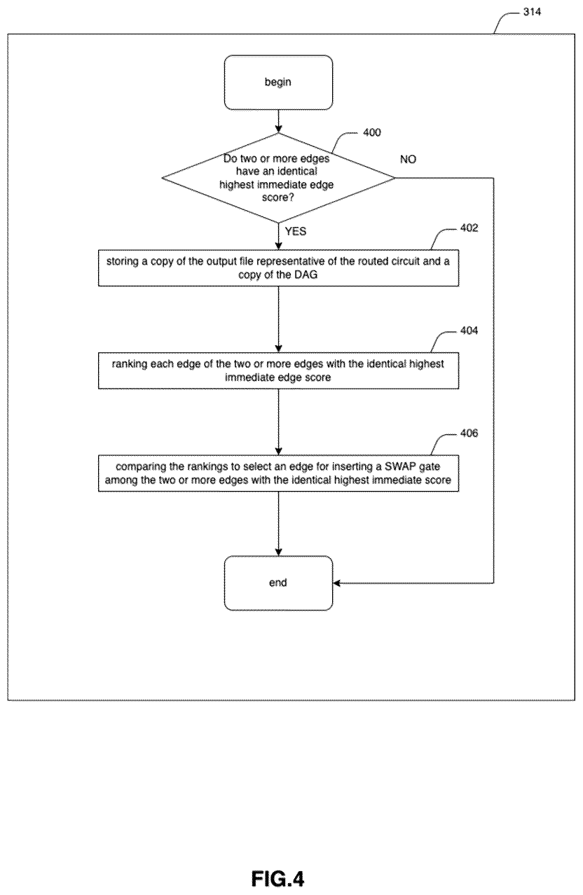

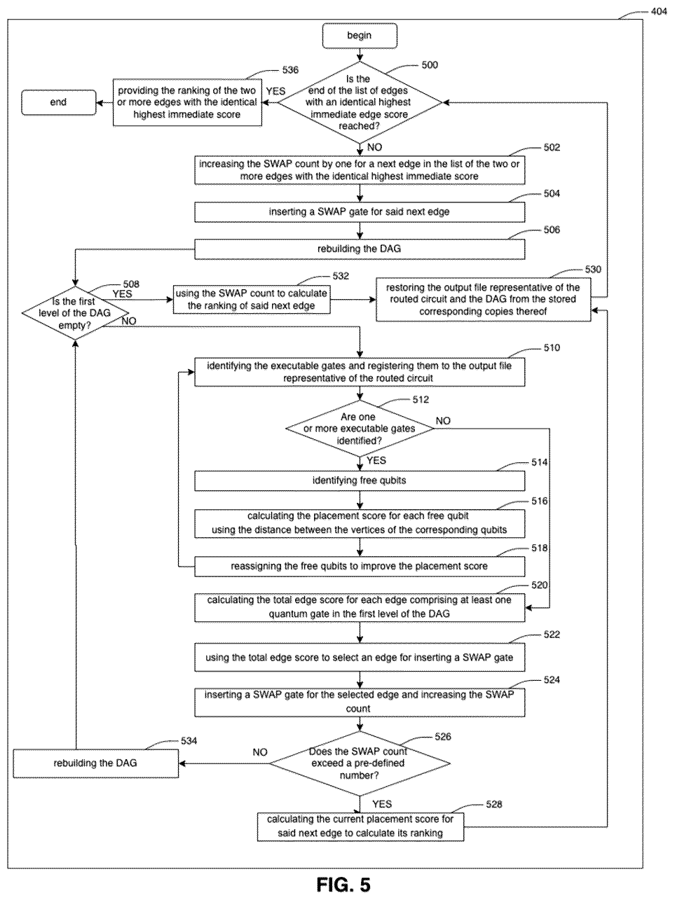

FIG. 4 is a flowchart of a procedure for selecting an edge for inserting a SWAP gate using a calculated edge score. If an immediate edge score is used in processing operation 312 of FIG. 3 and two or more edge scores are identical, then the method may use a decision tree mechanism to select an edge for inserting a SWAP gate in processing operation 314. The decision tree mechanism may be of various types. In some cases, the decision tree mechanism is such as the procedures described herein with respect to FIG. 4 and FIG. 5.

According to processing operation 400, if two or more edges have an identical highest immediate edge score, then a copy of the output file representative of the routed circuit and a copy of the DAG are stored according to processing operation 402.

According to processing operation 404, each edge of the two or more edges with the identical highest immediate edge score is ranked.

Now referring to FIG. 5, there is shown a flowchart of a procedure for ranking edges with an identical highest immediate score.

According to processing operation 500, if the end of the list of the two or more edges with an identical highest immediate score is reached the ranking of the edges is provided according to processing operation 536. If the end of the list is not reached, then according to processing operation 502 the SWAP count is increased by one for a next edge in the list of the two or more edges with the identical highest immediate score.

According to processing operation 504, a SWAP gate is inserted for the next edge in the list.

According to processing operation 506, the DAG is rebuilt taking into consideration the inserted SWAP gate.

Still referring to FIG. 5 and according to processing operation 508, if the first level of the DAG is empty, then the procedure moves to processing operation 532. If the first level of the DAG is not empty the procedure moves to processing operation 510.

According to processing operation 510, the executable quantum gates in the first level of the DAG are identified and registered to the output file representative of the routed circuit. In some cases, a two-qubit quantum gate in the first level is considered to be executable if the two qubits comprising the gate are assigned neighboring vertices. Once a quantum gate is identified and registered to the output file representative of the routed circuit, it is removed entirely from the DAG. Subsequently, the method looks for the next executable quantum gate in the DAG. A one-qubit quantum gate in the first level is always considered to be executable. During the process of searching for executable quantum gates, in some cases wherein there are more vertices in a graph representative of a quantum chip than there are qubits to be placed in the quantum circuit, there may be unoccupied vertices in the graph representative of the quantum chip. In such cases, if a qubit has not yet been used in any quantum gate registered in the output file representative of the routed circuit, it is free to be reassigned to a different vertex. These yet-to-be-executed qubits are referred to as “free qubits.”

Still referring to FIG. 5 and according to processing operation 512, if one or more executable gates are identified in processing operation 510, then according to processing operation 514 free qubits are identified. If no executable gates are identified in processing operation 510, then the procedure moves to processing operation 520.

According to processing operation 516, for each free qubit identified in processing operation 514 a placement score is calculated. For each two-qubit quantum gate comprising at least one free qubit, the placement score is calculated using the graph distance between the vertices of the corresponding qubits, scaled by a constant factor which is exponentiated by the level of the two-qubit quantum gate in the DAG comprising at least one free qubit. The constant factor may be any number between 0 and 1 inclusive. It is adjustable in order to achieve optimal performance for different types of circuits. A lower score indicates a closer placement of corresponding qubits of the quantum gates. A lower score therefore may indicate a better placement. The placement score is calculated to check if moving the free qubits from their designated vertices to a proposed one may lower the total graph distance. If it is so, according to processing operation 518, the free qubits are reassigned to new vertices to improve the placement score. If at least one free qubit is reassigned the procedure returns to processing operation 510.

Still referring to FIG. 5 and according to processing operation 520, for each edge connecting vertices that have at least one vertex assigned to a qubit comprising at least one quantum gate in the first level of the DAG the total edge score is calculated. The total edge score is the summation of an immediate score and the discounted score. For each edge under consideration the qubits assigned to the vertices connected by the edge are identified. At least one of the two identified qubits is a qubit comprising a quantum gate in the first level of the DAG. If a qubit comprises more than one quantum gate in the first level of the DAG, then the first such quantum gate in the first level is considered. The quantum two-qubit gate comprising an active qubit is then considered, the second qubit comprising the same quantum two-qubit gate is identified. In some cases, the inactive qubit and the second qubit identified while considering an edge may be different qubits, and the inactive vertex and the vertex the second qubit is assigned to may be different vertices. The immediate score of the edge under consideration is calculated using the graph distance between the active vertex and the vertex the second qubit is assigned to minus the graph distance between the inactive vertex and the vertex the second qubit is assigned to. The discounted score of the edge under consideration is calculated using all or a pre-defined number of the quantum gates in the first level and in the other levels of the DAG which comprise at least one of the two qubits assigned to the vertices at the ends of the edge under consideration. In the case of the discounted score the difference in the distances is exponentiated by the level of the gate in the DAG. In some cases, a high immediate or discounted edge score indicates a large reduction in distance if the SWAP gate is inserted for the edge, meaning the qubits belonging to the same gate are moved closer to each other.

Still referring to FIG. 5 and according to processing operation 522, an edge for inserting the SWAP gate is selected using the total edge score calculated in processing operation 520. The edge with the highest edge score is selected. If there are two two-qubit quantum gates in the first level consisting of four qubits which qubits are assigned to the vertices of the graph representative of the quantum chip structure satisfying the condition that the shortest distances between each pair of vertices share the same edge, the common edge is selected. In some cases, a SWAP gate is inserted to bring one of the aforementioned four qubits to one end of the common edge, such that both two-qubit quantum gates can be made executable with one additional swap after such operation.

Now referring to FIG. 6, if a SWAP gate is inserted between (Q8, Q7), then one additional SWAP gate between (Q8, Q6) can make both (Q2, Q6) and (Q5, Q8) executable. In the rest of the cases wherein two or more edge scores are identical and highest, an edge for inserting the SWAP gate is selected at random among the two or more edges with the identical highest score.

According to processing operation 524, a SWAP gate is inserted for the selected edge and the SWAP count is increased.

According to processing operation 526, if the SWAP count for the next edge in the list exceeds a pre-defined number then the procedure moves to processing operation 528. If the SWAP count for the next edge in the list does not exceed a pre-defined number, then the DAG is rebuilt taking into consideration the inserted SWAP gate according to processing operation 534.

Still referring to FIG. 5 and according to processing operation 528, the current placement score is calculated. The calculated current placement score is used to rank the next edge in the list. For each two-qubit quantum gate, the placement score is calculated using the graph distance between the vertices of the corresponding qubits, scaled by a constant factor which is exponentiated by the level of the two-qubit quantum gate on the DAG. The constant factor may be any number between 0 and 1 inclusive. It is adjustable in order to achieve optimal performance for different types of circuits. The placement score is then calculated for a pre-defined number of not-yet-executed gates in the quantum circuit. The ranking of the next edge in the list is calculated by summing over the placement scores of these gates.

According to processing operation 532, the ranking of the next edge in the list is calculated using the SWAP count of the next edge in the list. The ranking is given by −1*10\hat{ }(10−SWAP count).

According to processing operation 530, the output file representative of the routed circuit and the DAG are restored from the stored corresponding copies thereof.

Still referring to FIG. 5 and according to processing operation 536, the rankings of the two or more edges with the identical highest immediate score are provided.

Now referring back to FIG. 4 and according to processing operation 406 the rankings of the two or more edges with the identical highest immediate edge score are compared to select an edge among the two or more edges with the identical highest immediate edge score for inserting a SWAP gate.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

What is claimed is:

1. A method for constructing a circuit to allocate information qubits, said circuit comprising one or more quantum gates, the method comprising:
(a) using a graph representative of a quantum chip structure to implement a placement procedure on a list of two-qubit quantum gates to obtain an initial placement of said information qubits on said quantum chip structure;
(b) implementing a routing procedure to construct a routed circuit for said information qubits comprising said list of two-qubit quantum gates using said initial placement, wherein said routing procedure comprises a scoring system comprising discounted and not discounted scores; and
(c) providing an output representative of said routed circuit, wherein said output comprises an order of execution of said one or more quantum gates.

2. The method of claim 1, wherein said routed circuit is configured to allocate said information qubits on said quantum chip structure.

3. The method of claim 1, further comprising implementing said routed circuit on said quantum chip structure.

4. The method of claim 1, further comprising prior to (b) constructing at least one member of the group consisting of: a list of layers of said two-qubit quantum gates, an ordered list of said two-qubit quantum gates, a dependency graph, and a directed acyclic graph (DAG).

5. The method of claim 4, wherein constructing said DAG comprises, until an end of a list of not-yet-executed quantum gates from said list of two-qubit quantum gates, assigning each gate a level on said DAG, and wherein commutable gates are assigned a same level in said DAG.

6. The method of claim 1, further comprising providing said output representative of said routed circuit to an intermediate communication interface comprising a quantum chip controller to instruct said quantum chip structure to execute in the order of said provided output file representative of said routed circuit.

7. The method of claim 1, wherein said graph comprises vertices and edges, and wherein (b) comprises calculating a placement score based at least in part on distances between said vertices of said graph, wherein said vertices each corresponds to an information qubit of said information qubits.

8. The method of claim 7, wherein said distances between said vertices are scaled by a constant factor exponentiated by a level in said DAG of a two-qubit quantum gate.

9. The method of claim 7, further comprising:
(i) computing a Hamiltonian path of said quantum chip structure, wherein said Hamiltonian path is a path traversing said graph passing through each vertex of said graph once; and
(ii) using said Hamiltonian path to place said two-qubit quantum gates to obtain said initial placement.

10. The method of claim 7, wherein (b) comprises a randomized mixture of a greedy approach and a random approach.

11. The method of claim 7, wherein (b) comprises implementing said placement procedure a number of times and using said placement score to select said initial placement.

12. The method of claim 8, wherein (c) comprises, until no executable gates remain unevaluated in a first level of said DAG:
(i) identifying said executable gates in said first level of said DAG and registering them to said output representative of said routed circuit;
(ii) if one or more executable gates are identified in (i), then identifying zero or more free qubits and:
(1) for each free qubit calculating said placement score, scaled by said constant factor; and
(2) reassigning said free qubits to improve said placement score;
(iii) calculating an edge score for each edge in said first level in said graph, wherein said edge score is one of a discounted edge score or a not discounted edge score;
(iv) selecting an edge for inserting a SWAP gate using said edge score;
(v) inserting said SWAP gate for said edge selected in (iv); and
(vi) rebuilding said DAG at least in part by grouping executable gates into said first level.

13. The method of claim 12, wherein (i) and (ii) are repeated until no executable gates are identified.

14. The method of claim 12, wherein if said edge score is said not discounted edge score edge score and two or more edge scores are identical, then the method further comprises using a decision tree mechanism at (iv) to select said edge for inserting said SWAP gate.

15. The method of claim 14, wherein said decision tree mechanism at (iv) comprises:
(1) storing a copy of said output and a copy of said DAG;
(2) ranking each edge of two or more edges with an identical highest immediate score, wherein said ranking comprises, until an end of a list of said two or more edges with said identical highest immediate score:
a) increasing a SWAP count by one for a next edge in said list of said two or more edges with said identical highest immediate score;
b) inserting said SWAP gate for said next edge in said list of said two or more edges;
c) rebuilding said DAG;
d) calculating said ranking of said next edge in said list of said two or more edges; and
e) restoring said output representative of said routed circuit and DAG from said copy; and
(3) comparing said rankings to select an edge for inserting said SWAP gate among said two or more edges with said identical highest immediate score.

16. The method of claim 1, wherein said graph representative of said quantum chip structure comprises at least one of a two-dimensional directed graph or a two-dimensional undirected graph.

17. A system for constructing a circuit to allocate information qubits, said circuit comprising one or more quantum gates, the system comprising:
an intermediate communication interface comprising a controller configured to provide instructions to a quantum chip comprising physical qubits; and
a digital computer comprising a memory comprising an application with instructions for using a graph representative of a quantum chip structure to implement a placement procedure on a list of two-qubit quantum gates to obtain an initial placement of said information qubits on said quantum chip structure; for constructing a routed circuit to allocate said information qubits on a quantum chip structure; and for storing and providing an output representative of said routed circuit to said intermediate communication interface to be executed using said quantum chip.

18. The system of claim 17, further comprising a quantum chip for executing said routed circuit, wherein said quantum chip structure comprises physical qubits.

19. The system of claim 18, wherein said physical qubits comprise at least one of superconducting physical qubits or ion trap physical qubits.

20. The system of claim 17, wherein said intermediate communication interface comprises one or more of a field-programmable gate array (FPGA) and an application-specific integrated circuit (ASIC).
